(19) United States
(12) Patent Application Publication
(10) Pub. No.: US 2018/0147879 A1
(43) Pub. Date: May 31, 2018

(54) CUSTOMIZATION OF SECURITY DISPLAY DEVICES

(71) Applicant: NATIONAL RESEARCH COUNCIL OF CANADA, Ottawa (CA)

(72) Inventors: Keith MORTON, St-Bruno-de-Montarville (CA); Teodor VERES, Montreal (CA); Liviu CLIME, Longueuil (CA)

(73) Assignee: NATIONAL RESEARCH COUNCIL OF CANADA, Ottawa (CA)

(21) Appl. No.: 15/570,078

(22) PCT Filed: May 11, 2016
(86) PCT No.: PCT/CA2016/050537

§ 371 Date: Oct. 27, 2017

Related U.S. Application Data
(60) Provisional application No. 62/159,427, filed on May 11, 2015.

(51) Int. Cl. B42D 25/328; B42D 25/387; B81B 7/00; B42D 25/324; B42D 25/369; C09D 11/101

(52) U.S. Cl. CPC B42D 25/328; B42D 25/387; B81B 7/00; B42D 25/351; B42D 25/369; C09D 11/101; B42D 25/324

(57) ABSTRACT

A security device comprising a microstructure and one or more curable fluids, in which the microstructure is configured to direct the one or more curable fluids from a local application zone of the microstructure to one or more regions of the microstructure prior to curing each curable fluid. Alternatively, the security device may comprise a microstructure; and one or more cured fluids; in which each cured fluid is derived from a corresponding curable fluid that is directed by the microstructure from a local application zone of the microstructure to one or more regions of the microstructure prior to curing each curable fluid. The microstructure can have a depth of at least 100 nm, and a spacing aspect ratio (depth to height) greater than 1:10. A process for fabricating a security device is also described.

### TECHNICAL FIELD

The present disclosure relates to security display devices. In particular, it relates to directed wicking of multifunctional liquids and particle inks for customization of security display devices.

### BACKGROUND

The following background discussion includes information that may be useful in understanding the present device. It is not an admission that any of the information provided herein is prior art or relevant to the presently claimed device, or that any publication specifically or implicitly referenced is prior art.

Optical document security features provide rapid visual feedback to users wishing to authenticate a particular product or product packaging, a currency or payment method, or a variety of frequently-used identification documents. Such features are intended to build confidence and provide assurance that subsequent purchases, transactions or permissions granted are correct.

U.S. 2011/0076395 discloses a holographic structure created by embossing a polymeric substrate and applying an ink or varnish to selected areas of the hologram to provide non-holographic regions. The holographic regions provide a design—for example, alphanumeric characters. Ink may be printed on the reverse side of the substrate and over the location of the holographic regions.

AU 2011253683 discloses the production of hologram on a packaging, whereby a radiation-curable coating containing particulate metal is coated on the packaging. The coating is partially cured. Subsequently, a shim containing the negative of a hologram is contacted with the partially cured coating, followed by full curing of the coating.

U.S. Pat. No. 6,987,590 discloses optical structures that exhibit the effects of relief patterns, together with another design pattern (e.g. alphanumeric characters). A patterned layer of reflective material is applied to certain areas of the relief structure to provide the other design pattern. An optically active coating (e.g. a color shifting film) may also be applied over the whole structure to provide other optical effects. Relief patterns may be microstructural and formed by thermoforming (e.g. embossing) a polymeric substrate. The reflective layer is metallic and may be formed by photolithography or gravure printing.

U.S. Pat. No. 6,97,590 discloses a security element comprising a holographic grating that has non-diffractive sub-areas formed therein, in which visual elements incorporated to form printed matter that can only be seen by viewing the hologram from oblique angles. It further discloses that ink jet printing can be used to apply the visual elements.

U.S. Pat. No. 8,015,919 discloses a process in which a diffraction grating is formed on a substrate and a metallic ink is deposited on at least a portion of the diffraction grating. The structural features of the grating have a low aspect ratio. Further, the ink coating completely covers the structural features and the diffractive pattern itself does not appear to play a role in where the ink coating ends up.

U.S. 2015/0137502 discloses a security element comprising reconfigurable microstructures formed on a polymeric substrate that reconfigure upon application and subsequent evaporation of a volatile fluid. It is the dynamic changes to the liquid that provide for the security measures.

U.S. 2014/0239628 discloses a security device that include a fluid or fluids within the device. Dynamic changes to the fluid within the device indicate if a document is legitimate or a counterfeit copy.

A common and widely-accepted overt document security feature is the standard grating hologram which exhibits a scintillating range of vibrant and distinct coloration reflected from shallow diffraction gratings embossed on a plastic layer above a thin reflective metal layer (usually aluminum). Embossed feature thicknesses are less than a few microns with limited aspect ratios (1:1 or 1:2). Examples range from simple uni-directional gratings to grating areas having many directional angles so as to catch incident light from a variety of positions and orientations. More complex security features incorporate such gratings into intricate shapes, (company) logos and detailed artwork, where the true holographic recording and recreation of three dimensional images is widely used. The value of such holograms is currently under pressure as the quality and quantity of counterfeits increases along with world-wide availability of lasers and dot matrix mastering tools, eroding confidence in these shallow, reflective-type features.

A second class of holograms is based on light transmission through a window inscribed with diffractive features. Amplitude transmission holograms require opaque or translucent diffractive patterns, while phase holograms require no a priori metallization and, as such, can be more difficult to copy since the optical quality of the transmission window must be maintained. Vivid coloration in this class of holograms arises from path length difference between spectral colours as incident light travels through the security display device. Both reflection and transmission holograms are limited in terms of counterfeiting resistance as they have limited feature depths and are therefore susceptible to copying by replica molding. Moreover, cost pressures in the fabrication favour polymer-based materials and additive printing over top of standardized security features.

### SUMMARY

To address these limitations, the present device combines a standardized fabrication process platform of polymer forming (that leads to high aspect ratio structures) together with multifunctional or particle-laden inking to produce optical security features that can be custom printed industrially by using a self-wetting process driven by capillarity.

The process of customizing the security device comprises filling the device with one or more curable fluids that fill the device in a predetermined manner. The one or more fluids are guided by the microstructures within the device. The size, shape, geometry and spacing of the microstructures direct and enhances wicking. While the percolation of the one or more curable fluids is dynamic, the final security device comprises the cured fluid(s). As such, the security device observable to the user is static and does not retain dynamic fluid effects.

The device, process for manufacturing the device and the microstructure will first be described in their general form, and then their implementation in terms of preferred embodiments will be detailed hereafter. These embodiments are intended to demonstrate the principles of the microstructure, the device and the process, and the manner of their implementation. The device, microstructure and process in their broadest and more specific forms will then be further described, and defined, in each of the individual claims which conclude this specification.

Unless the context dictates the contrary, all ranges set forth herein should be interpreted as being inclusive of their endpoints, and open-ended ranges should be interpreted to include commercially practical values. Similarly, all lists of values should be considered as inclusive of intermediate values unless the context indicates the contrary.

In one aspect of the present invention, there is provided a security device comprising: a microstructure; and one or more curable fluids; wherein the microstructure is configured to direct the one or more curable fluids from a local application zone of the microstructure to one or more regions of the microstructure prior to curing each curable fluid.

In another aspect of the present invention, there is provided a security device comprising: a microstructure; and one or more cured fluids; wherein each cured fluid is derived from a corresponding curable fluid; and the microstructure is configured to direct the one or more curable fluids from a local application zone of the microstructure to one or more regions of the microstructure prior to curing each curable fluid.

In another aspect of the present invention, there is provided a microstructure for use in a security device, wherein the microstructure directs one or more curable fluids from a local application zone of the microstructure to one or more regions of the microstructure.

In another aspect of the present invention, there is provided a process for fabricating a security device, comprising the steps of: forming a microstructure onto a substrate, the microstructure configured to direct one or more curable fluids from a local application zone of the microstructure to one or more regions of the microstructure; introducing the one or more curable fluids at the local application zone; and applying a curing process to the one or more curable fluids after the one or more curable fluids has percolated to the one or more regions of the microstructure.

Where the security device comprises one or more curable fluids, each curable fluid percolates one or more regions of the microstructure prior to curing. In addition a curing process can be applied to the one or more curable fluids after the microstructure directs the one or more curable fluids. The curing process may be selected from the group consisting of solidification, UV-cure, thermoset and evaporation. Furthermore, an external field may be applied prior to, or during, the curing process; the external field can be selected from the group consisting of magnetic, electric, gravitational and any combination thereof.

Where the security device comprises one or more curable fluids, the security device may include a first layer of a first curable fluid that is added to the microstructure, and then cured; followed by a second layer of a second curable fluid that is placed on the first layer, and then the second layer is cured. Or, the security device may include a first layer of a first curable fluid that is added to the microstructure, and then cured; followed by a second layer of a second curable fluid that is placed on the first layer, followed by an external field that is applied to the second layer while the second layer is cured. Alternatively, the security device may include a first curable fluid that is placed in a first region of the microstructure; a second curable fluid that is placed in a second region of the microstructure; followed by curing of each region.

Where the security device comprises one or more curable fluids, the security device may comprise a stack of first and second microstructures on opposing sides of a plane of the security device, wherein a first curable fluid is added to the first microstructure, a second curable fluid is added to the second microstructure, and the fluids are either encapsulated or cured.

Where the security device comprises one or more cured fluids, the security device may comprise a first and second cured fluid, wherein a layer of the first cured fluid is above a layer of the second cured fluid. Alternatively, the security device may comprise a first cured fluid in a first region of the microstructure; and a second cured fluid in a second region of the microstructure.

Where the security device comprises one or more cured fluids, the security device may comprise a stack of first and second microstructures on opposing sides of a plane of the security device, wherein the first microstructure comprises a first cured fluid; and the second microstructure comprises a second cured fluid. In addition, the security device may comprise a plurality of stacks.

In both types of security devices described above, the microstructure may have a depth of at least 100 nm, or a spacing aspect ratio of depth to width greater than 1:10. The microstructure may comprise a multiplicity of posts, or alternatively, comprise a multiplicity of holes within a matrix. Furthermore, the microstructure may be embossed, cast, or molded. In addition, it may be constructed, for example, from a material selected from the group consisting of thermoplastic, thermoplastic elastomer, thermoset and UV-curable.

In both types of security devices described above, the microstructure can be a diffraction microstructure for hologram display. In such an example, the diffraction microstructure may include one or more overlayed diffraction gratings, in which case, at least one of the diffraction gratings can have a periodicity smaller than the periodicity of the diffraction microstructure. Furthermore, the diffraction microstructure and at least one or more overlayed diffraction grating may provide non-visible diffractive effects.

In both types of security devices described above, at least one curable fluid may have a refractive index similar or equal to a refractive index of material used to fabricate the microstructure. Alternatively, at least one curable fluid may have a refractive index different from a refractive index of material used to fabricate the microstructure.

In both types of security devices described above, at least one least one curable fluid used in the security device may be a pure substance. In addition, at least one curable fluid may comprise microparticles or nanoparticles. As an example, at least one curable fluid can be an ink. In addition, the microparticles or nanoparticles may be selected from the group consisting of glass beads, silica beads, polystyrene beads, polyethylene beads, magnetic beads, Janus particles, plasmonic nanoparticles, superparamagnetic nanoparticles and any combination thereof. In addition, the microparticles or nanoparticles can have a shape selected from the group consisting of a sphere, an ellipsoid, a cube, a pyramid, a rod, a plate, a polyhedron, and any combination thereof.

In both types of security devices described above, at least one curable fluid can be a multifunctional fluid. For example, at least one curable fluid may comprise microparticles or nanoparticles that are reflective, transparent, pigmented, non-pigmented, fluorescent, magnetic, plasmonic, bi-morphic, or any combination thereof. As an example, at least one curable fluid may comprise UV fluorescent particles.

In both types of security devices described above, at least one curable fluid can be a formulation that comprises a solvent. Examples of curable fluids that do not have a solvent base, include UV-crosslinkable monomers and polymer formulations, and groups of thermosplastic and thermoset polymers. These can be used directly to percolate through the security device microstructures before being cured in place to provide the desired customization effect.

Solvent-based curable fluids include both aqueous and organic based formulations that dynamically wet the intended portions of the larger security microstructures. In this instance, the solubilized monomer or polymer remains in, and around, the security device microstructures following drying and solvent evaporation. In some embodiments, the residual solute can then be further cured in place by UV-crosslinking, thermoplastic hardening or thermosetting.

In addition, various particle suspensions can be in incorporated into both the solvent-free and solvent-based curable fluids, such that the particles remain embedded in the device, following fluid drying or curing.

The security device may be constructed such that a first layer of a first curable fluid is added to the microstructure, the first layer is then cured; a second layer of a second curable fluid is placed on the first layer, and the second layer is then cured. Alternatively, a first layer of a first curable fluid may be added to the microstructure; the first layer is then cured. A second layer of a second curable fluid is then placed on the first layer, and then an external field is applied to the second layer while the second layer is cured. As yet another alternative, a first curable fluid can be placed in a first region of the microstructure; a second curable fluid is then placed in a second region of the microstructure; and each layer is then cured.

The security device may comprise a stack of first and second microstructures on opposing sides of a plane of the security device, wherein a first curable fluid can then be added to the first microstructure, the second curable fluid can then be added to the second microstructure, and the curable fluids are either encapsulated or cured. The security device can be built of a plurality of such stacks.

With regards to the microstructure, it can have a depth of at least 100 nm, and a spacing aspect ratio of depth to width greater than 1:10. Furthermore, it may comprise a plurality of pixilated regions; and may have walls between each region. It may also comprise a multiplicity of posts of different sizes, shapes, geometry, and spacing for enhanced wicking of one or more curable fluids within the microstructure. The posts can be triangular, cylindrical, oval, hexagonal, square, rectangular, elliptical, or any combination thereof. Alternatively, instead of posts, the microstructure may comprise a multiplicity of holes within a matrix. The microstructure may be embossed, cast or molded; and may be constructed, for example, from a material selected from the group consisting of thermoplastic, thermoplastic elastomer, thermoset and UV-curable.

As described above, the microstructure can comprise of posts of different sizes, shapes, geometry, and spacing for enhanced wicking of one or more fluids within the microstructure. For enhanced wicking the aspect ratio of these various structures and spacings is chosen such that the ratio of the depth to the lateral size (aspect ratio) of the structures or spacings is greater than 1:10. An example of a range of an aspect ratio is from 1:10 to 50:1. Another example of a range of an aspect ratio is from 1:10 to 10:1. Yet another example of a range of an aspect ratio is from 1:3 to 10:1. Generally the depth and width of the spacing between the posts and wall is chosen to best enhance and direct fluid wicking; the width of the guiding structures is then chosen to provide the overall intended visual effect.

With regards to the process for fabricating a security device, the features of the curable fluids microstructure, and curable process described above, also apply.

The device provides an additional degree of security to a basic diffractive security display device by using the rapid percolation of a fluid or particle-laden fluid into the micro or nanostructures of the fabricated security display device. This thwarts counterfeit copies of the original diffractive security display device by allowing post-production customization and incorporation of unique identifiers or security tags into the security display device. Customization of the base security element is achieved by using direct wicking to delineate a specific artwork, logo or design.

The device may further comprise the following elements: a micro/nanofabricated diffractive hologram security display element having a non-negligible depth in order to support fluid filling or fluid contact line pinning using forms, patterns, orientations and arrangements designed to enhance capillary forces and direct wicking; and a fluid or particle-laden fluid having one, or a plurality of, specific functional properties, that upon drying or curing within the structured diffractive hologram security display element, provides customization or personalization to the structured diffractive hologram security display element.

The device includes micro/nanostructured optical security features based on the physical structure of the device. This specific structure directs and distributes curable liquids (or curable particle-laden liquid suspensions) in order to define additional artwork within the features. In this manner, documents with customizable, yet highly-secure features can be created. These documents are resistant to counterfeiting, and are both overt (for human unassisted authentication) and covert for machine-readability. The fluid suspensions can have a single distinguishing property, or a combination of distinguishing properties, that include for example, wetting characteristics, refractive index characteristics, drying characteristics, UV cross-linking or thermoset characteristics. Additionally, the use of particle-laden liquid suspensions can provide additive, multifunctional attributes that include various permutations of coloured, fluorescent, magnetic, nanostructured or plasmonic colloidal particles that span both a range of sizes, from several nanometers to tens of micrometers, as well as a range of symmetric or asymmetric shapes, including pyramids, cubes, spheres, ellipsoids, rods and plates. Combining targeted inking with self-directed, capillary-driven filling of functional particles in ink-like formulations can create hierarchical, counterfeit-resistant optical security features while also providing significant reductions in production costs by delivering customization to a wide range of customers based on the same core optical security technology.

In addition, there is provided a method to use the intrinsic form and layout of diffractive devices to drive, direct, enhance and control the wicking and filling of fluids, functional fluids and particle-laden fluids. In so doing, there are provided additional hierarchical security levels, security tagging and most importantly, specific customization and/or personalization of the base holographic security display device. Specific customization can be added to structured optical document security features by directed wicking and inking of multifunctional, feature-filling fluids by directed printing of custom logos or other designs.

The multifunctional liquids and/or particle-laden liquid suspensions can incorporate a range of possible functional combinations, including wetting properties, specific refractive index matching properties, drying properties, UV cross-linking or thermoset properties. Furthermore, particle laden-suspensions can provide additive, multifunctional attributes by including various permutations of coloured, fluorescent, magnetic, nanostructured or plasmonic colloidal particles. These particles can have a range of diameters from several nanometers to tens of micrometers, and can have a variety of shapes (spherical to platelets, symmetry or asymmetric). As such, it is possible to create customizable document security display devices that have both overt (i.e. human unassisted) and covert (i.e. machine-readable) security anti-counterfeit features.

The foregoing summarizes the principal features of the security device and some of its optional aspects. The security device may be further understood by the description of the embodiments which follow.

Wherever ranges of values are referenced within this specification, sub-ranges therein are intended to be included within the scope of the security device unless otherwise indicated. Where characteristics are attributed to one or another variant of the security device, unless otherwise indicated, such characteristics are intended to apply to all other variants of the security device where such characteristics are appropriate or compatible with such other variants.

### BRIEF DESCRIPTION OF FIGURES

The patent or application file contains at least one drawing executed in color. Copies of this patent or patent application publication with color drawing(s) will be provided to the Office upon request and payment of the necessary fee.

FIG. 1 illustrates a first embodiment of a security device.

FIG. 2 illustrates the targeted inking of a high-aspect ratio transmission hologram microstructures.

FIGS. 3a and 3b illustrate pixilation of diffractive micro/nanostructures hologram structures.

FIGS. 4a and 4b illustrates the curing of functional liquids in regions of the diffractive micro/nanostructure holograms of FIGS. 3a and 3b.

FIGS. 5a-5k illustrate examples of pixel structures, a representative diffractive projection, and use of index-matching.

FIG. 6 illustrates a variety of clear window designs, artwork and lettering within a larger diffractive hologram field.

FIG. 7 illustrates a higher magnification image of the sample display device of FIG. 6.

FIGS. 8a and 8b illustrate a wide area view and detailed view, respectively, of negative tone-type single well, single-pixel filling.

FIG. 9 is an SEM image of a variety of discrete microfabricated structures having specific shapes, spacings, orientations and arrangements.

FIG. 10 illustrates a second embodiment of the security device.

FIGS. 11a and 11b illustrate a third embodiment of the security device.

FIG. 12 illustrates a fourth embodiment of the security device.

FIGS. 13a-13e illustrate a fifth embodiment of the security device.

FIG. 14 illustrates a sixth embodiment of the security device.

FIG. 15 illustrates the concept of functional filling of multiple segmented diffractive security features.

FIGS. 16A and 16B illustrate stacking of multiple diffractive security features.

FIG. 17 shows a SEM view of a guided particle drying on a diffractive hologram.

### DETAILED DESCRIPTION OF PREFERRED EMBODIMENTS

The following is given by way of illustration only and is not to be considered limitative of the security device. Many apparent variations are possible without departing from the scope thereof.

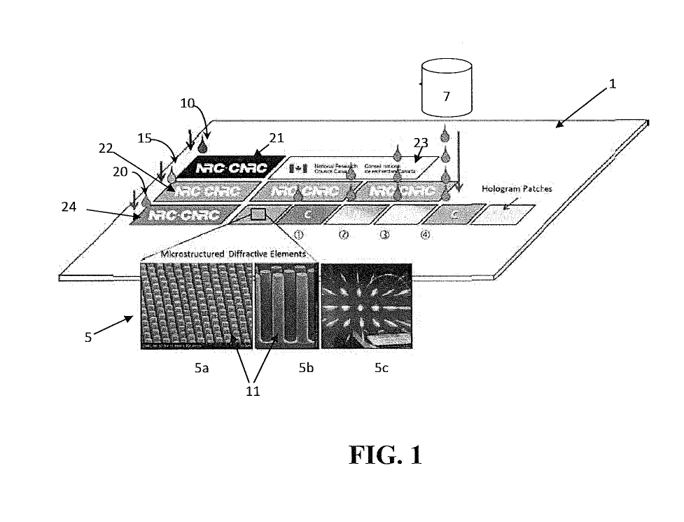

FIG. 1 illustrates incorporation of multiple security features into a security document (1). In particular, FIG. 1 shows a process whereby phase holograms are encoded through sequential filling with a variety of (multi)functional fluids (10), (15) and (20).

A high-aspect ratio diffractive optical security element (5) is shown in the inset of FIG. 1. This element is hot-embossed or UV-cured in an optically-transparent plastic material. The size of the element can vary from 1 mm to many tens of centimeters and take the form of any shape or artwork outline. The diffractive features are deep, ranging from 100 nm to 100 μm deep and thus are more difficult to reproduce and replicate than most current diffractive reflection holograms.

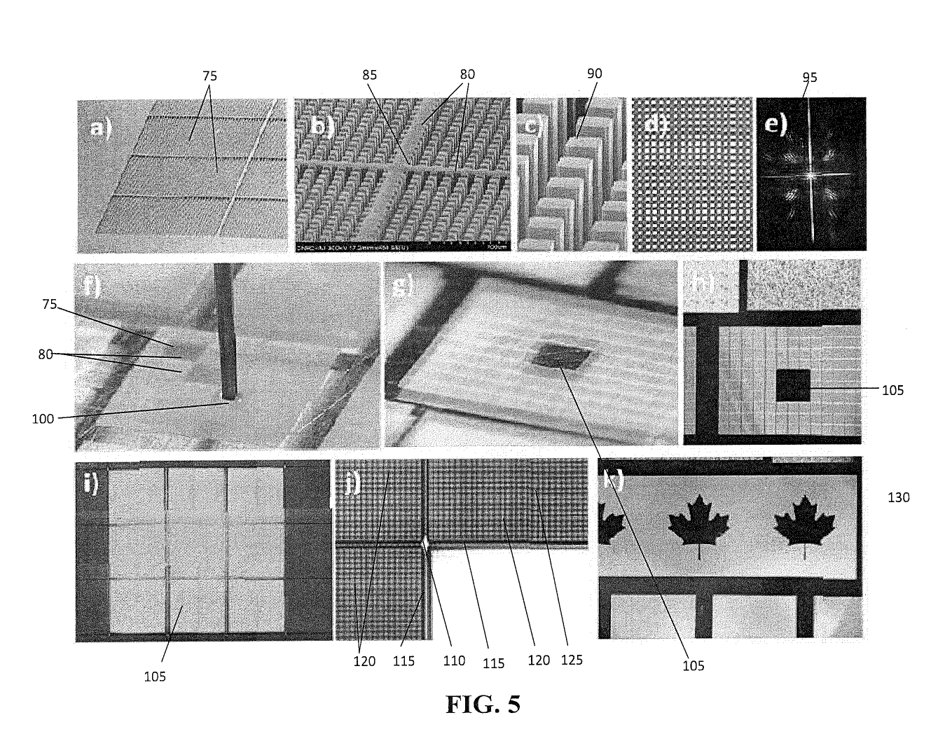

The inset (5a-5c) also shows an example of the diffraction pattern that arises from the regular, periodic array of deep posts (10) (arranged here using a parallelogram basis). Similar effects are possible with the post pattern inverted so that the pillars are actually holes within a plastic matrix. The diffractive element is viewed in FIG. 5c) in transmission using a point source backlight such as an LED or light bulb. The light source does not need to be coherent or monochromatic (e.g. a laser), but a laser can be used to project the diffraction pattern. The transparent, optical clarity of the transmission hologram (5c) is shown here where the separation between adjacent diffraction maxima is directly related to the periodic spacing of the plastic microfabricated structures. Spectral dispersion is evident for each diffraction maxima showing the splitting of the white light source into its component rainbow spectrum. Diffraction efficiency is also seen as the zero-order (white) spot at the center is reduced to a qualitatively similar intensity to the nearest neighbour first-order diffraction spots.

An inking apparatus (7), such as an ink jet, screen, gravure or flexo printing system, deposits multifunctional liquids (10), (15) and (20) that percolate the microstructured diffractive elements. Directed wicking is enhanced and controlled by tailoring the microstructure shape, spacing and arrangement of individual diffractive elements to shape and direct the liquid flow direction and distance travelled. The document security display device can incorporate multiple security features and customizations including standard printed features (21), nanostructured plasmonic features (22), high aspect ratio security holograms (23) and enhanced filling of high aspect ratio security holograms (24) with multifunctional fluids.

The inset (5a-5c) shows high magnification details (scanning electron micrograph, SEM) of representative holographic security elements that have a high-aspect ratio that are designed to enhance liquid wetting within the structure.

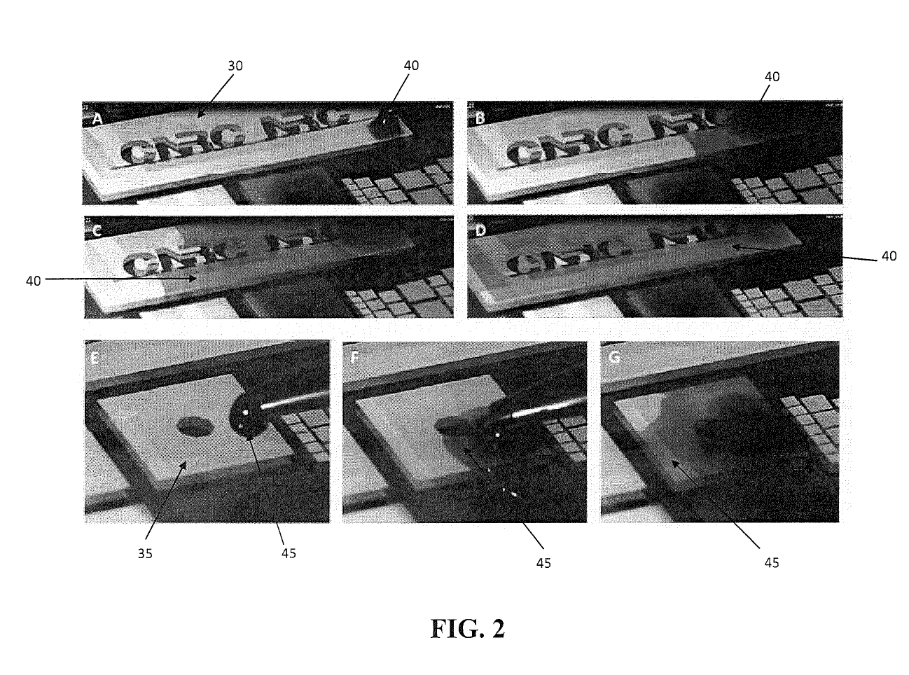

FIG. 2 demonstrates an example of directed wicking and liquid filling of a diffractive element. Here, the rapid liquid spreading of an ink (40, 45) dispensed into a microfabricated hologram (30, 35) patch is shown. In the figure, successive video frame stills, capture the fast, self-wicking and full-feature filling characteristics of the structured hologram. In Figs A-D, the patch (30) has a size of 3 cm×1 cm; for E-G, the patch (35) size is 1 cm×1 cm. Both patches are populated with arrays of pillars similar to those shown in the inset of FIG. 1. In both (D) and (G) representative logo features are completely encircled and remain unaffected. These logos are in a larger diffractive feature field.

The wide area of the manufactured transmission hologram, combined with the depth of microfabricated features, allows liquids to penetrate, wick and flow through the array of posts by capillary forces. By appropriate channeling or pixilation of the post array, or by manipulating the specific shape and proximity of the posts, directed fluid flow within the post array is possible.

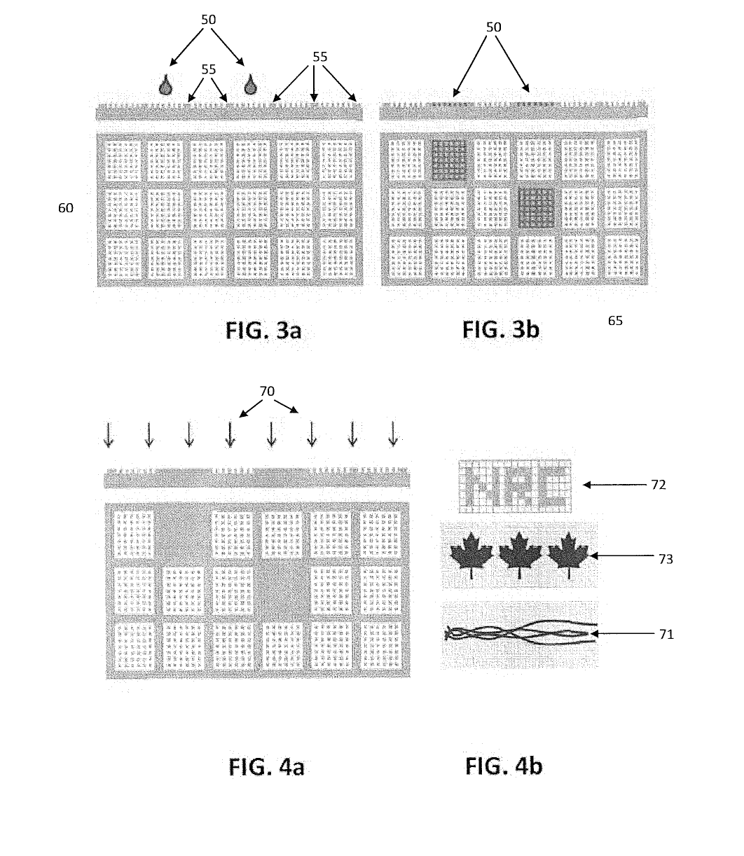

FIGS. 3 and 4 illustrate pixilation of diffractive micro/nanostructures hologram structures. As shown in FIG. 3a, a functional fluid (50) is deposited within a delineated portion or pixel area (60). The walls (55) between these individual regions allows for selective inking, wicking and filling within discrete regions and the creation of custom patterns. While the pixel area (60) shown here is square, different shapes, or even artwork outlines, are possible.

The fluid then fills the pixel area (65) shown in FIG. 3b and can then be cured (70) as shown in FIG. 4a to form any number of customized or personalized images, artwork (71), lettering (72) or logos (73) as illustrated in FIG. 4b. The functional fluid can be a simple ink, making the custom features dark or coloured with the larger diffractive hologram feature field. Alternatively, the functional fluid can be tailored to have a refractive index that matches the original diffractive hologram polymer material. In this manner, both the light scattering and diffractive effects are erased, creating a clear, optically transparent window within the larger diffractive hologram field.

FIGS. 5a to 5d illustrate SEM images of various pixel structures, while FIG. 5e illustrates a representative diffractive projection. FIGS. 5f to 5k illustrate the use of index matching material to create a clear window, a clear design or a clear logo within the diffractive field.

FIG. 5a is an SEM Microscope image (tilted-view) showing a side-by-side array of diffractive pixels (75) in a larger field, delineated by microstructured walls. Each pixel comprises an array of pillars (having a depth of from 100 nm to 100 μm) that form the base diffractive optical security element. FIG. 5b illustrates detail of intersecting walls (80) at pixel corners (85). FIG. 5c illustrates the fine detail of FIGS. 5a and 5b showing individual diffractive pillar elements (90). A top-view of the diffractive elements is shown in FIG. 5d, while FIG. 5e illustrates a diffractive hologram (95) viewed in transmission with a point white light as source.

Subsequent filling of the pixel structures (75) shown in FIGS. 5f-5j, with a liquid (100), shows clear delineation of the liquid within the bounds of the pixel. In FIG. 5f, a video frame still of the dynamics of fluid filling and wetting shows that liquids remain within the boundaries of each pixilation unit. When filled (as in FIG. 5f), the walls (80) separating each pixel (75) provide definition and resolution.

An example of functional filling and curing, using an index-matching polymer is shown in FIG. 5g. Here, nine pixels (105) are used to form a square within a larger field. The newly-formed window is transparent. In FIG. 5h, diffuse backlighting is used to show that the newly-filled diffractive elements (105) no longer exhibit diffraction. Furthermore, FIG. 5i provides a top-view of the nine filled pixels (105) shown in FIGS. 5g and 5h. The smooth polymer-filled surface reflects light more than the deep-pillar structures. FIG. 5j illustrates detail of one corner (110) of one filled pixel showing the pixel walls (115) and three neighbouring pixels (120) with individual diffractive elements (125) intact.

FIG. 5k illustrates an example of clear window logo (130) designs that can be written into a previously defined diffractive field, thereby demonstrating the concept of curing or drying functional liquids to create logos or other personalizing artwork defined within a larger hologram field.

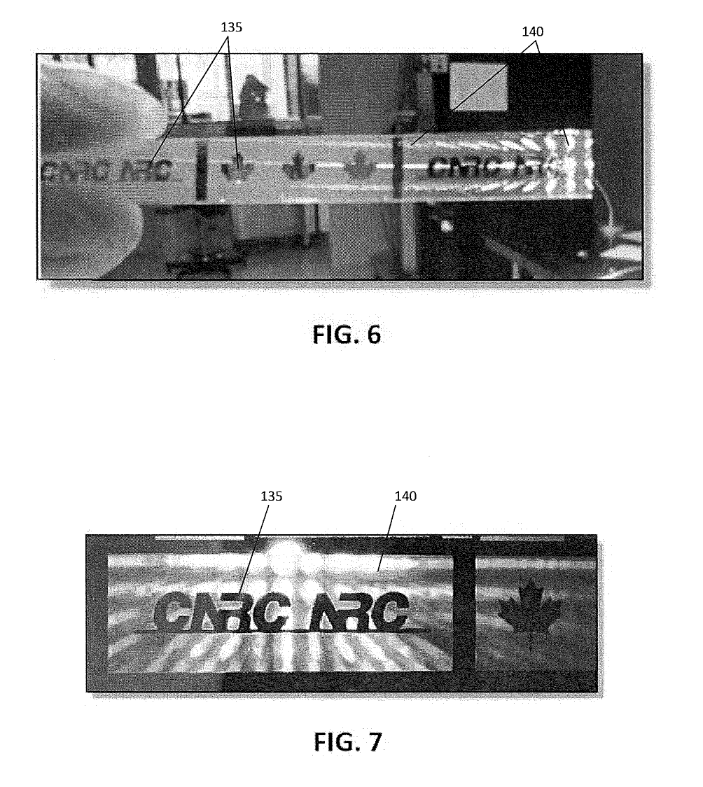

To further demonstrate the post-fabrication customization of diffractive security display elements, examples of clear windows to delineate lettering, logos or other artwork elements are shown in both FIGS. 6 and 7.

FIG. 6 illustrates a variety of clear (135) window designs, artwork and lettering within a larger diffractive hologram field (140), as viewed in transmission using a backlit point white light source. The wide-angle view illustrates diffractive hologram (135) features having clear windows (135) (maple leaves) or lettering (NRC Logo) embedded by customization within a field of diffractive post arrays (140). Here, Mie scattering of ambient white light gives the diffractive element a whitish, cloudy look helping to contrast the optically clear window area (135) while vibrant transmission mode diffraction and spectral colour dispersion is viewed by the dynamic movement of the security display element between the point light source and the viewer. FIG. 7 shows a higher magnification image of the sample display device of FIG. 6, thereby highlighting the clear window effect (135) of the lettering and artwork within the diffractive array field (140).

Individual diffractive element features can have either a positive or a negative tone. In a positive tone, diffractive elements are, on average, more pillar like, allowing fluid filling in and around the individual elements (as shown, for example, in FIG. 1).

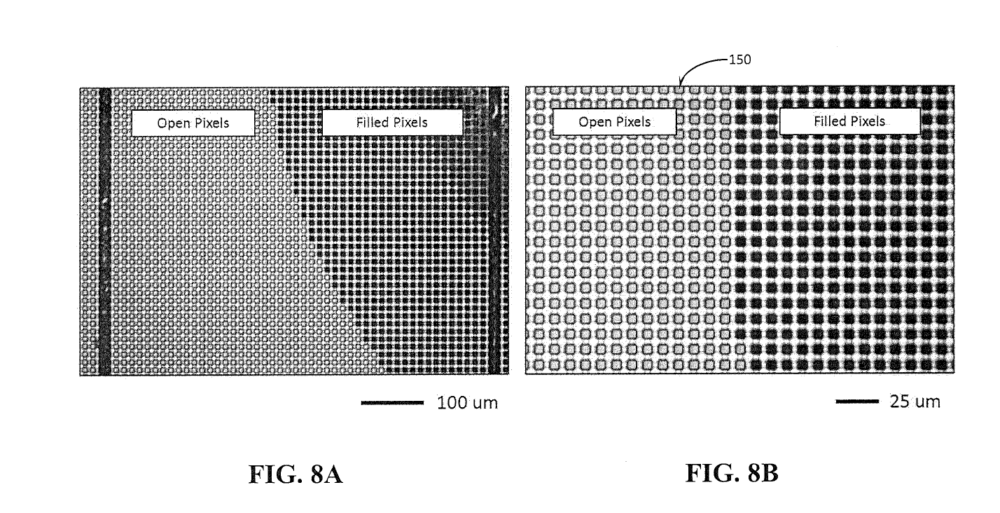

For negative tone-type elements, pixilation can be reduced to the actual size of the micron-scale diffractive feature itself. In this case, individual pixels can each be filled to create high-resolution, pixel-level (single-well) customization, thereby providing a projected diffraction pattern. Illustration of negative tone-type single well, single-pixel filling is shown in FIGS. 8a and 8b. FIG. 8a illustrates a wide area view (high contrast), while FIG. 8b illustrates a detailed view or FIG. 8a. Here, the individual pixels (150) or wells are selectively filled to create phase or amplitude contrast required to project the desired diffraction pattern.

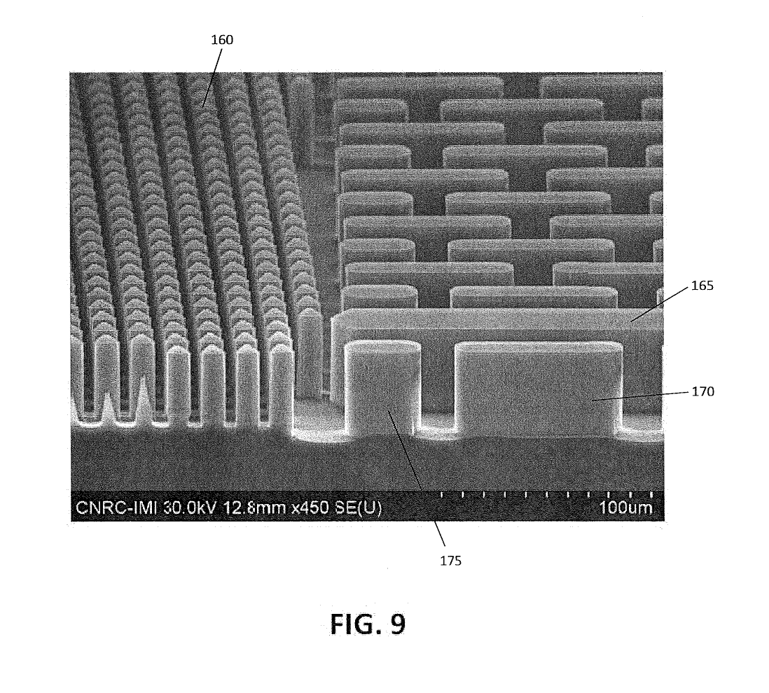

FIG. 9 is an SEM image of a variety of discrete microfabricated structures (160, 165, 170, 175) having specific shapes, spacings, orientations and arrangements designed to enhance and direct self-wicking for multifunctional fluids. Each set of structures give both unique diffractive signatures and distinct wetting properties through capillary force engineering. For example, the larger offset oval features on the right (165, 170, 175) allow directed, rapid and uninterrupted propagation of fluid front, while the smaller, sharp, triangular features (160) restrict flow propagation so that rows fill sequentially and only one at a time.

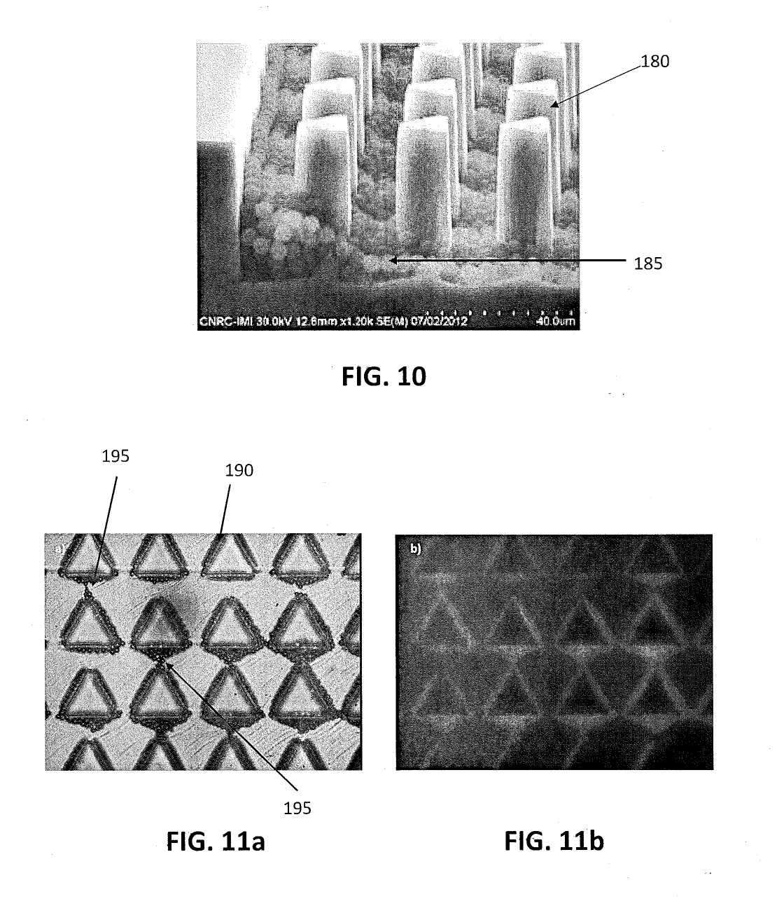

Further customization of holograms is possible using particle-laden fluids, in which the fluid is used as a means to wick and carry various particle entities through the diffractive hologram security element. FIG. 10 illustrates an embodiment in which the diffractive micro/nanostructured hologram is backfilled, not with a homogeneous liquid, but a particle-laden liquid that is later dried or cured in place. This provides further customization and further covert security elements. Here, 5 μm polystyrene beads (185) are suspended in a liquid which is wicked through the microstructured diffractive features of the security display device by capillary wicking. Upon solvent drying, the beads are close-packed around the posts (180). This provides an example of a secondary security feature in addition to the base diffractive security feature that overlays a photonic crystal lattice with tunable close packing. The lattice can range from an ordered photonic crystal lattice to complete disorder. As such, it is useful as a uniquely identifying fingerprint.

FIG. 11a illustrates a second example where the diffractive micro/nanostructured hologram is backfilled with a particle-laden liquid that is dried or cured in place. Here, the example of filling with 4 μm diameter fluorescent blue polystyrene spheres (190) is shown, in which capillary bridges (195) form at the point of the triangle post tips. Here by post shape choice, as well as nearest neighbour inter-post spacing, can be combined with specific particle diameters to tune unique drying patterns. These can be used as uniquely identifying security features since these features are not easily copied—the directed self-assembled nature of the particle drying process is not repeatable. No two samples are alike. In this particular embodiment, a simple image capture can be compared to archived originals for authentication. FIG. 11(b) illustrates the example of FIG. 11(a) viewed under fluorescent excitation. This highlights the additional and covert fluorescent blue emission of the particles, which provides specific, covert verification “security tags” within the diffractive hologram structure.

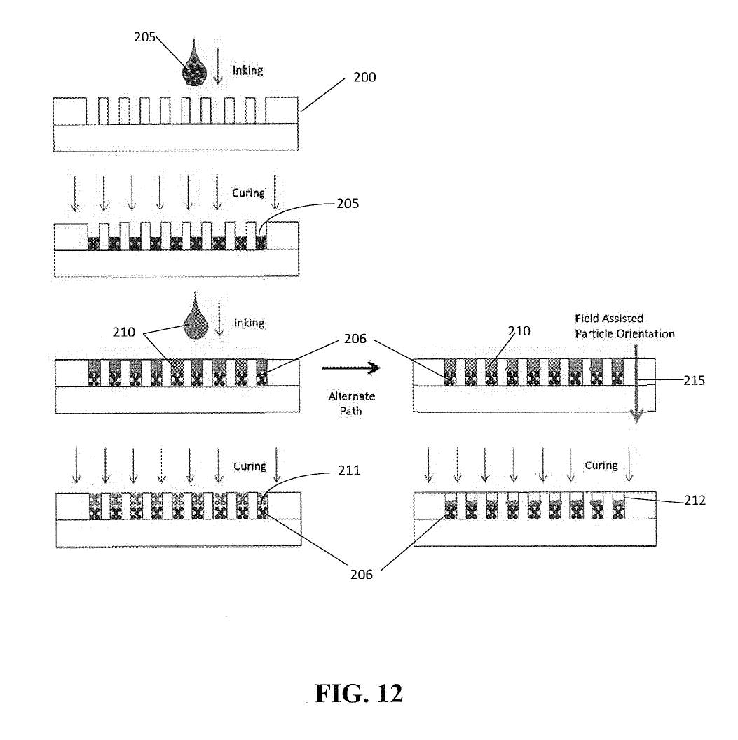

The concepts illustrated in FIGS. 10 and 11 can be extended to include multi-layer and external field assisted control of functional particles during inking, as shown in FIG. 12, which illustrates this dual back-filling capability within the same diffractive hologram structure (200). A first filling (i.e. inking, followed by curing) deposits functional particles (205) throughout the hologram structure (200) as part of a curable polymer matrix that is dispensed and accurately metered by volume, guided filling or solvent evaporation. Curing then results in the first cured form (206). A second layer of functional particles (210) can then be inked into the hologram to create a two layer structure. The second layer can also be cured to provide the second cured form (211) atop the first cured form (206). Many multi-layers can be then be built up in a similar fashion.

In an alternate path, one or more of the functional particle moieties can be oriented; close packed or otherwise rearranged in-situ, post-inking using an applied external field (215) such as gravity, electric or magnetic fields and surface tension forces during solvent evaporation. Curing following the application of an external field (215) results in a third cured form (212).

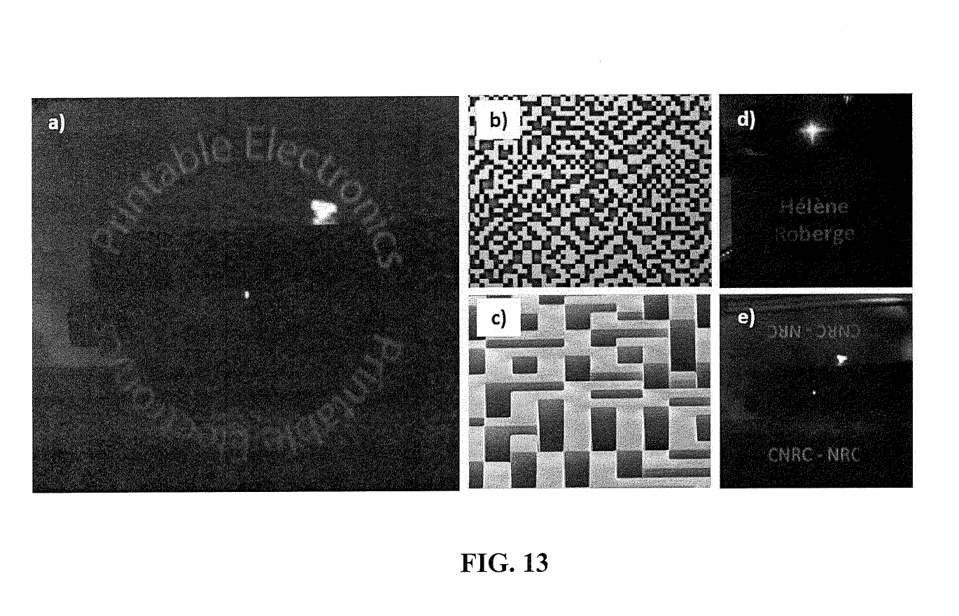

Other embodiments include fluid filling or particle-laden fluid filling of more elaborate diffractive hologram types such as the example shown in FIG. 13a which demonstrates a particular form of the diffractive transmission holograms were the diffraction maxima themselves are arranged to form lettering, names, logos or other artwork. Here the clear, transparent hologram structures are illuminated from behind using monochromatic light such as a LED or other point light source. These computer generated-type diffractive transmission holograms, as shown in FIG. 13b (top view micrograph) and FIG. 13c (tilt-view scanning electron microscope image), are more robust than simple arrays and also provide wicking and directed liquid wetting properties for post-fabrication customization. For example, personalization using a person's name or a company logo, as seen in the diffractive transmission hologram as shown in the embodiment presented in FIGS. 13d and 13e, can be further secured by functional fluid filling and particle flow in and around the diffracting microstructures.

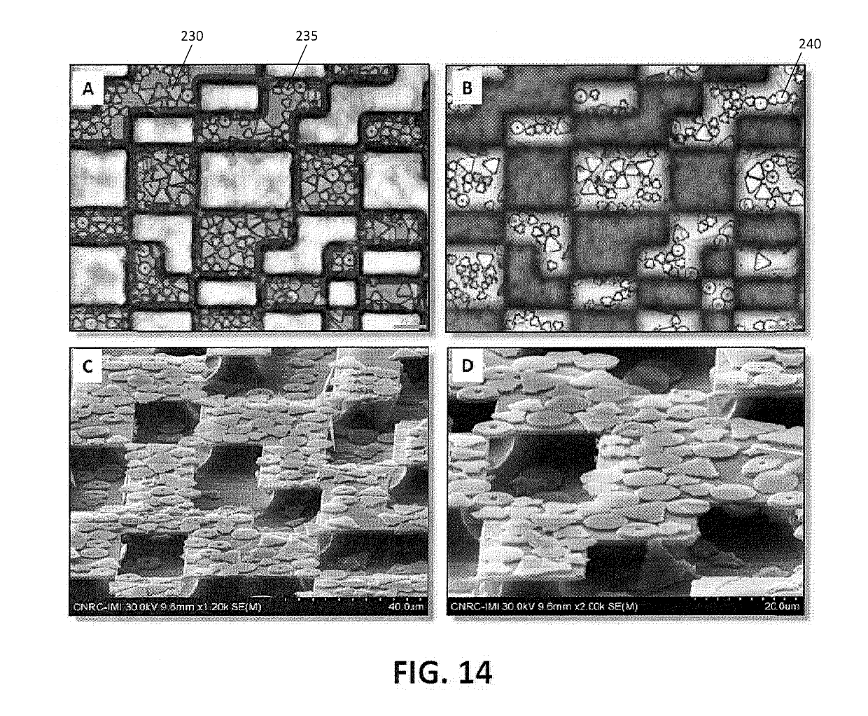

FIG. 14 illustrates an embodiment where the two-level diffractive micro/nanostructured holograms of the type shown in FIG. 13 are backfilled with particle-laden liquids containing multi-shaped microplatelets. The computer-generated hologram diffractive micro/nanostructures are filled with 2-5 μm diameter, 500 nm-thick silicon dioxide platelet particles. This provides additional security features. The exact close packing, structured-enhanced and capillary driven as-dried in place position of the platelet particles amid the diffractive structure can provide a unique and counterfeit deterring fingerprint to the original projected images, while providing interesting and attractive coloration in its own right.

FIGS. 14a-14d illustrates the use of non-spherical particles (230) dried on the mesas (235) (as shown in FIG. 14a) and channels (240) (as shown in FIG. 14b) of a diffractive hologram microstructure. Here, the aspect ratio of the microstructure is approximately 1:3. In these figures, the particles (230) have different shapes plate-like features. In particular, FIGS. 14c and 14d illustrate oblique view SEM images. The many shapes and sizes together with the overall coded diffractive microstructures combine to drive particle self-assembly and form a unique, close-packed arrangement. The individual platelet particles (230) have the additional added security element of thin film interference colours as well.

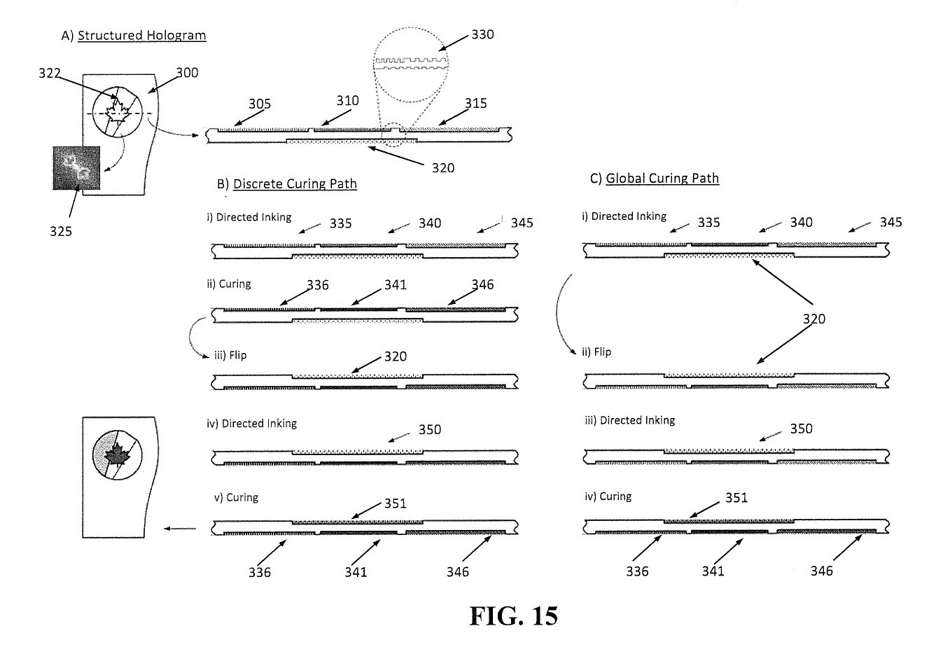

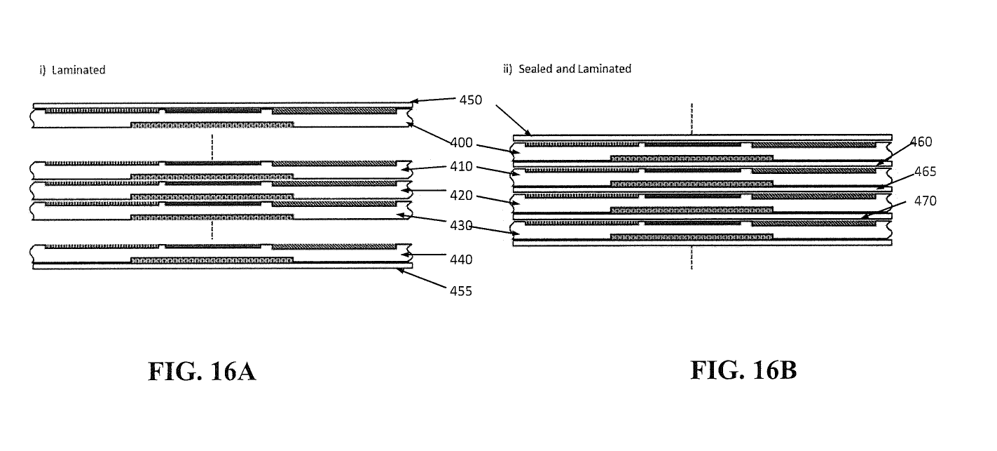

FIGS. 15A-15C illustrate the concept of functional fluid filling of independently addressable hologram levels for both adjacent and double-sided diffractive security features. FIG. 15A illustrates an example of double-side security features. In FIG. 15A, both a top view and a cross-sectional view of the security feature (300) are shown. The security feature comprises several independently addressable diffractive hologram regions (305), (310), (315), (320) that together form the artwork or logo (322). An example of the projected hologram (325) is shown in the top-view inset, while the cross-sectional view inset (330) shows the detail of the diffractive structures shown with different periods, depths and aspect ratios.

Directed inking of various multi-functional fluids (335), (340), (345) and (350) are shown in FIGS. 15B and 15C.

FIG. 15B illustrates an example of directed inking in which fluids 335, 340 and 345 fill respective hologram regions 305, 310 and 315 in step (i). This is followed by curing the fluidsbin step (ii), in which the cured fluids are represented by (336), (341) and (346). The device (300) is turned over in step (iv), for filling region (320) with fluid (350) in step (v), followed by curing in step (vi) to form cured fluid (351). The resulting image is shown as (323).

FIG. 15C shows an example where both sides of the security device (300) are first filled with fluids 335m 340 and 345; then flipped in step (ii), followed by filling region (320) with fluid (350). The curing step is then carried out in step (iv), resulting in cured fluids (336), (341), (346) and (351), as in FIG. 15B.

It is understood that fluids (335), (340), (345) and (350) can be different fluids comprising the full range of possible functionalities with or without additional suspended functional particles.

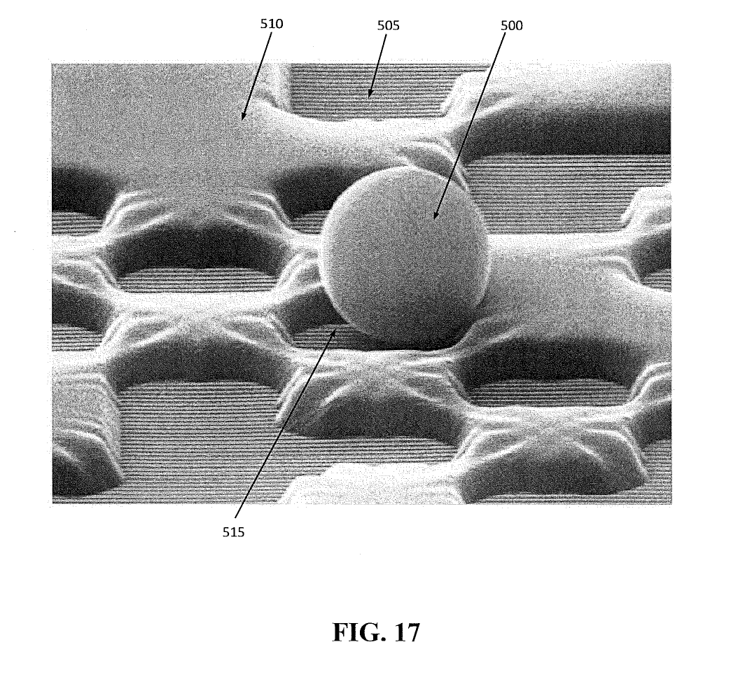

FIG. 17 shows at a higher magnification, SEM image of a large functional particle (400) pinned and trapped within one of the many diffracting feature details (510) to highlight the inclusion of nanostructured diffraction gratings (505) (shown here as 700 nm pitch) incorporated along the floor of the hologram structures (510). Here the additional fine nanostructured gratings (505) embossed into the hologram structure (510) are highlighted. The fine nanogratings (505) have a pitch of several hundred nanometers and are hot embossed simultaneously with the larger diffractive computer generated hologram microstructures. The addition of this highly visible diffraction grating (505) builds in further overt visual security features into the embossed computer generated transmission hologram (510), which is then further supplemented by the directed drying of the security tag particle (500) which is driven by surface tension forces during solvent ink evaporation into just one corner (515) of the hologram microstructure (510). These images demonstrate the following interrelated security hierarchies in an embodiment:
Vibrant, eye catching visible diffraction grating;
Computer Generated Transmission Hologram Projecting Legible Logos or Lettering; and
Overlay of functional fluid or particles positioned by directed wicking and drying.

In summary, the customization of general holograms by post-fabrication filling and particle placement provides highly secure, individual customization. This customization can come from permutations and combinations of a plurality of fluid properties and particle properties.

The displacement of the fluid moiety into the hologram structures is dependent on the following parameters each of which can be tuned to give the desired effect:
Diffractive elements: form, aspect ratio, shape, nearest neighbour distances, orientation.
Density
Viscosity
Surface Tension
Surface—Fluid Contact Angle
Contact Angle Hysteresis
Refractive Index
Solvent volatility and drying
Solvent curing (UV, thermoset or other)
Constituent Suspended Dye, Pigments or Particles

The addition of specific particles to the liquid to create a functional suspension as well as the final security effect is dependent on the particle moiety for which permutations and combinations can include the following:
Particle material
Particle density
Individual Particle size (relative to diffractive features)
Multiple Particle sizes
Particle shape (symmetric or asymmetric)
Multiple Particle Shapes
Reflective or transparent
Coloured (dyed or pigmented) or Clear
Fluorescent
Magnetic
Plasmonic
Bi-morphic/Janus Type
Flow Field Oriented
External Field (Gravity, Magnetic, Electric) Oriented

In some embodiments, the numbers expressing quantities of ingredients, properties such as concentration, reaction conditions, and so forth, used to describe and claim certain embodiments of the invention are to be understood as being modified in some instances by the term “about.” Accordingly, in some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the invention are approximations, the numerical values set forth in the specific examples are reported as precisely as practicable. The numerical values presented in some embodiments of the invention may contain certain errors necessarily resulting from the standard deviation found in their respective testing measurements.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

All methods described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Markush groups used in the appended claims.

It should be apparent to those skilled in the art that many more modifications besides those already described are possible without departing from the inventive concepts herein. The inventive subject matter, therefore, is not to be restricted except in the scope of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refers to at least one of something selected from the group consisting of A, B, C. . . . and N, the text should be interpreted as requiring only one element from the group, not A plus N, or B plus N, etc.

The foregoing has constituted a description of specific embodiments showing how the device may be applied and put into use, and how the device may be fabricated. These embodiments are only exemplary. The security device, and a process for fabricating the same, is further described in its broadest, and more specific aspects, and defined in the claims which now follow.

These claims, and the language used therein, are to be understood in terms of the variants of the security devices and processes which have been described. They are not to be restricted to such variants, but are to be read as covering the full scope of the security devices and processes as defined in the claims that now follow.

We claim:

1. A security device comprising:
a) a microstructure; and
b) one or more curable fluids;
wherein the microstructure is configured to direct the one or more curable fluids from a local application zone of the microstructure to one or more regions of the microstructure prior to curing each curable fluid.

2. The security device of claim 1, wherein a curing process is applied to the one or more curable fluids after the microstructure directs the one or more curable fluids.

3. The security device of claim 2, wherein the curing process is selected from the group consisting of solidification, UV-cure, thermoset and evaporation.

4. The security device of claim 2 or 3, wherein an external field is applied prior to, or during, the curing process.

5. The security device of claim 4, wherein the external field is selected from the group consisting of magnetic, electric, gravitational and any combination thereof.

6. The security device of any one of claims 1 to 5, wherein a first layer of a first curable fluid is added to the microstructure, the first layer is cured; a second layer of a second curable fluid is placed on the first layer, and the second layer is cured.

7. The security device of any one of claims 1 to 5, wherein a first layer of a first curable fluid is added to the microstructure; the first layer is cured; a second layer of a second curable fluid is placed on the first layer; an external field is applied to the second layer while the second layer is cured.

8. The security device of any one of claims 1 to 5, wherein a first curable fluid is placed in a first region of the microstructure; a second curable fluid is placed in a second region of the microstructure; and each region is cured.

9. A security device comprising:
a) a microstructure; and
b) one or more cured fluids;
wherein each cured fluid is derived from a corresponding curable fluid; and the microstructure is configured to direct the one or more curable fluids from a local application zone of the microstructure to one or more regions of the microstructure prior to curing each curable fluid.

10. The security device of claim 9, comprising a first and second cured fluid, wherein a layer of the first cured fluid is above a layer of the second cured fluid.

11. The security device of claim 9 comprising a first cured fluid in a first region of the microstructure; and a second cured fluid in a second region of the microstructure.

12. The security device of any one of claims 1 to 11, wherein the microstructure has a depth of at least 100 nm.

13. The security device of any one of claims 1 to 12, wherein the microstructure has a spacing aspect ratio of depth to width greater than 1:10.

14. The security device of any one of claims 1 to 13, wherein the microstructure is embossed, cast, or molded.

15. The security device of any one of claims 1 to 14, wherein the microstructure is constructed from a material selected from the group consisting of thermoplastic, thermoplastic elastomer, thermoset and UV-curable.

16. The security device of any one of claims 1 to 15, wherein the microstructure is a diffraction microstructure for hologram display.

17. The security device of claim 16, wherein the diffraction microstructure includes one or more overlayed diffraction gratings.

18. The security device of claim 17, wherein at least one of the diffraction gratings has a periodicity smaller than a periodicity of the diffraction microstructure.

19. The security device of claim 17 or 18, wherein the diffraction microstructure and the at least one or more overlayed diffraction grating provide non-visible diffractive effects.

20. The security device of any one of claims 1 to 19, wherein at least one curable fluid has a refractive index similar or equal to a refractive index of material used to fabricate the microstructure.

21. The security device of any one of claims 1 to 19, wherein at least one curable fluid has a refractive index different from a refractive index of material used to fabricate the microstructure.

22. The security device of any one of claims 1 to 21, wherein at least one curable fluid is a pure substance.

23. The security device of any one of claims 1 to 21, wherein at least one curable fluid comprises microparticles or nanoparticles.

24. The security device of claim 23, wherein at least one curable fluid is an ink.

25. The security device of claim 23, wherein the microparticles or nanoparticles are selected from the group consisting of glass beads, silica beads, polystyrene beads, polyethylene beads, magnetic beads, Janus particles, plasmonic nanoparticles, superparamagnetic nanoparticles and any combination thereof.

26. The security device of claim 23, wherein the microparticles or nanoparticles have a shape selected from the group consisting of a sphere, an ellipsoid, a cube, a pyramid, a rod, a plate, a polyhedron, and any combination thereof.

27. The security device of any one of claims 1 to 26, wherein at least one curable fluid is a multifunctional fluid.

28. The security device of claim 27, wherein at least one curable fluid comprises microparticles or nanoparticles that are reflective, transparent, pigmented, non-pigmented, fluorescent, magnetic, plasmonic, bi-morphic, or any combination thereof.

29. The security device of claim 28, wherein at least one curable fluid comprises UV fluorescent particles.

30. The security device of any one of claims 1 to 29, wherein the microstructure comprises a multiplicity of posts.

31. The security device of any one of claims 1 to 29, wherein the microstructure comprises a multiplicity of holes within a matrix.

32. The security device of any one of claims 1 to 5, comprising a stack of first and second microstructures on opposing sides of a plane of the security device, wherein a first curable fluid is added to the first microstructure, a second curable fluid is added to the second microstructure, and the fluids are either encapsulated or cured.

33. The security device of claim 9, comprising a stack of first and second microstructures on opposing sides of a plane of the security device, wherein the first microstructure comprises a first cured fluid; and the second microstructure comprises a second cured fluid.

34. The security device of claim 32 or 33, comprising a plurality of stacks.

35. A microstructure for use in a security device, wherein the microstructure directs one or more curable fluids from a local application zone of the microstructure to one or more regions of the microstructure.

36. The microstructure of claim 35, wherein the microstructure has a depth of at least 100 nm.

37. The microstructure of claim 35 or 36, wherein the microstructure has a spacing aspect ratio of depth to width greater than 1:10.

38. The microstructure of any one of claims 35 to 37, wherein the microstructure comprises a plurality of pixilated regions; and walls between each region.

39. The microstructure of any one of claims 35 to 38, comprising a multiplicity of posts of different sizes, shapes, geometry, and spacing for enhanced wicking of one or more curable fluids within the microstructure.

40. The microstructure of claim 39, wherein the posts are triangular, cylindrical, oval, hexagonal, square, rectangular, elliptical, or any combination thereof.

41. The microstructure of any one of claims 35 to 38, wherein the microstructure comprises a multiplicity of holes within a matrix.

42. The microstructure of any one of claims 35 to 41, wherein the microstructure is embossed, cast, or molded.

43. The microstructure of any one of claims 35 to 42, wherein the microstructure is constructed from a material selected from the group consisting of thermoplastic, thermoplastic elastomer, thermoset and UV-curable.

44. A process for fabricating a security device, comprising the steps of:
a) forming a microstructure onto a substrate, the microstructure configured to direct one or more curable fluids from a local application zone of the microstructure to one or more regions of the microstructure;
b) introducing the one or more curable fluids at the local application zone; and
c) applying a curing process to the one or more curable fluids after the one or more curable fluids has percolated to the one or more regions of the microstructure.

45. The process of claim 44, wherein the microstructure has a depth of at least 100 nm.

46. The process of claim 44 or 45, wherein the microstructure has a spacing aspect ratio of depth to width greater than 1:10.

47. The process of any one of claims 44 to 46, wherein the microstructure comprises a plurality of pixilated regions; and walls between each region.

48. The process of any one of claims 44 to 47, wherein the microstructure comprises a multiplicity of posts of different sizes, shapes, geometry, and spacing for enhanced wicking of the one or more curable fluids within the microstructure.

49. The process of claim 48, wherein the posts are triangular, cylindrical, oval, hexagonal, square, rectangular, elliptical, or any combination thereof.

50. The process of any one of claims 44 to 47, wherein the microstructure comprises a multiplicity of holes within a matrix.

51. The process of any one of claims 44 to 50, wherein the microstructure is embossed, cast, or molded.

52. The process of any one of claims 44 to 51, wherein the microstructure is constructed from a material selected from the group consisting of thermoplastic, thermoplastic elastomer, thermoset and UV-curable.

53. The process of any one of claims 44 to 52, wherein the microstructure is a diffraction microstructure for hologram display.

54. The process of claim 53, wherein the diffraction microstructure includes one or more overlayed diffraction gratings.

55. The process of claim 54, wherein at least one of the diffraction gratings has a periodicity smaller than a periodicity of the diffraction microstructure.

56. The process of claim 54 or 55, wherein the diffraction microstructure and the at least one or more overlayed diffraction grating provide non-visible diffractive effects.

57. The process of any one of claims 44 to 56, wherein the curing process is selected from the group consisting of solidification, UV-cure, thermoset and evaporation.

58. The process of any one of claims 44 to 57, wherein an external field is applied prior to, or during, the curing process of step (c).

59. The process of claim 58, wherein the external field is selected from the group consisting of magnetic, electric, gravitational and any combination thereof.

60. The process of any one of claims 44 to 59, wherein at least one curable fluid has a refractive index similar or equal to a refractive index of material used to fabricate the microstructure.

61. The process of any one of claims 44 to 59, wherein at least one curable fluid has a refractive index different from a refractive index of material used to fabricate the microstructure.

62. The process of any one of claims 44 to 61, wherein at least one curable fluid is a pure substance.

63. The process of any one of claims 44 to 61, wherein at least one curable fluid comprises microparticles or nanoparticles.

64. The process of claim 63, wherein at least one curable fluid is an ink.

65. The process of claim 63, wherein the microparticles or nanoparticles are selected from the group consisting of glass beads, silica beads, polystyrene beads, polyethylene beads, magnetic beads, Janus particles, plasmonic nanoparticles, superparamagnetic nanoparticles and any combination thereof.

66. The process of claim 63, wherein the microparticles or nanoparticles have a shape selected from the group consisting of a sphere, an ellipsoid, a cube, a pyramid, a rod, a plate, a polyhedron, and any combination thereof.

67. The process of any one of claims 44 to 66, wherein at least one curable fluid is a multifunctional fluid.

68. The process of claim 67, wherein at least one curable fluid comprises microparticles or nanoparticles that are reflective, transparent, pigmented, non-pigmented, fluorescent, magnetic, plasmonic, bi-morphic, or any combination thereof.

69. The process of claim 68, wherein at least one fluid comprises UV fluorescent particles.

70. The process of any one of claims 44 to 69, wherein a first layer of a first curable fluid is added to the microstructure, the first layer is cured; a second layer of a second curable fluid is placed on the first layer, and the second layer is cured.

71. The process of any one of claims 44 to 69, wherein a first layer of a first curable fluid is added to the microstructure; the first layer is cured; a second layer of a second curable fluid is placed on the first layer; and an external field is applied to the second layer while the second layer is cured.

72. The process of any one of claims 44 to 69, wherein a first curable fluid is placed in a first region of the microstructure; a second curable fluid is placed in a second region of the microstructure; and each region is cured.

73. The process of any one of claims 44 to 69, comprising a stack of first and second microstructures on opposing sides of a plane of the security device, wherein a first curable fluid is added to the first microstructure, a second curable fluid is added to the second microstructure, and the fluids are either encapsulated or cured.

74. The process of claim 73 comprising a plurality of stacks.
